(19) United States
(12) Patent Application Publication
(10) Pub. No.: US 2019/0042056 A1
(43) Pub. Date: Feb. 7, 2019

(54) AVOIDING NOISE WHEN USING MULTIPLE CAPACITIVE MEASURING INTEGRATED CIRCUITS

(71) Applicant: Cirque Corporation, Salt Lake City, UT (US)

(72) Inventors: Brian Monson, Farmington, UT (US); David C. Taylor, West Jordan, UT (US)

(73) Assignee: Cirque Corporation, Salt Lake City, UT (US)

(21) Appl. No.: 16/132,246

(22) Filed: Sep. 14, 2018

Related U.S. Application Data
(63) Continuation-in-part of application No. 15/233,132, filed on Aug. 10, 2016, now abandoned.
(60) Provisional application No. 62/204,248, filed on Aug. 12, 2015.

(51) Int. Cl. G06F 3/041; G06F 3/044; G06F 3/038; G01R 29/26

(52) U.S. Cl. CPC G06F 3/0418; G01R 29/26; G06F 3/0383; G06F 3/044

(57) ABSTRACT

A system and method for enabling noise avoidance between multiple capacitive touch sensing circuits operating in a same device and which may interfere with each other, wherein a master controller is coupled to all of the capacitive touch sensing circuits to prevent them from using measurement frequencies and from jumping to new measurement frequencies that may interfere with each other, thereby allowing the capacitive touch sensing circuits to function properly.

### CROSS-REFERENCE TO RELATED APPLICATIONS

This application, under 35 U.S.C. § 119, claims the benefit of U.S. Provisional Patent Application Ser. No. 62/204,248 filed on Aug. 12, 20015, and is a continuation-in-part of application Ser. No. 15/233,132, filed Aug. 10, 2016, and entitled “Avoiding Noise When Using Multiple Capacitive Measuring Integrated Circuits” both of the contents of which are hereby incorporated by reference herein.

### FIELD OF THE DISCLOSURE

This disclosure relates generally to touch sensors that use capacitive sensing technology. Specifically, the disclosure pertains to a system and method for avoiding noise when using multiple capacitive touch sensing circuits, and particularly interference from one to another.

### BACKGROUND

There are several designs for capacitive touch sensing circuits which may take advantage of a system and method for providing a system that enables simultaneous use of capacitive touch sensing circuits in a same device. It is useful to examine the underlying technology of the touch sensors to better understand how any capacitive touch sensor can take advantage of the presently disclosed embodiments.

The CIRQUE® Corporation touchpad is a mutual capacitance-sensing device and an example is illustrated as a block diagram in FIG. 1. In this touchpad 10, a grid of X (12) and Y (14) electrodes and a sense electrode 16 are used to define the touch-sensitive area 18 of the touchpad. Typically, the touchpad 10 is a rectangular grid of approximately 16 by 12 electrodes, or 8 by 6 electrodes when there are space constraints. Interlaced with these X (12) and Y(14) (or row and column) electrodes is a single sense electrode 16. All position measurements are made through the sense electrode 16.

The CIRQUE® Corporation touchpad 10 measures an imbalance in electrical charge on the sense line 16. When no pointing object is on, or in proximity to, the touchpad 10, the touchpad circuitry 20 is in a balanced state, and there is no charge imbalance on the sense line 16. When a pointing object creates imbalance because of capacitive coupling when the object approaches or touches a touch surface (the sensing area 18 of the touchpad 10), a change in capacitance occurs on the electrodes 12, 14. What is measured is the change in capacitance, but not the absolute capacitance value on the electrodes 12, 14. The touchpad 10 determines the change in capacitance by measuring the amount of charge that must be injected onto the sense line 16 to reestablish or regain balance of charge on the sense line 16.

The system above is utilized to determine the position of a pointing object, or a finger, on, or in proximity to, a touchpad 10 as follows. This example describes row electrodes 12 and is repeated in the same manner for the column electrodes 14. The values obtained from the row 12 and column 14 electrode measurements determine an intersection which is the centroid of the pointing object on, or in proximity to, the touchpad 10.

In the first step, a first set of row electrodes 12 are driven with a first signal from P, N generator 22, and a different but adjacent second set of row electrodes 12 are driven with a second signal from the P, N generator. The touchpad circuitry 20 obtains a value from the sense line 16 using a mutual capacitance measuring device 26 that indicates which row electrode 12 is closest to the pointing object. However, the touchpad circuitry 20 under the control of some microcontroller 28 cannot yet determine on which side of the row electrode 12 the pointing object is located, nor can the touchpad circuitry 20 determine just how far the pointing object is located away from the electrode. Thus, the system shifts by one electrode the group of electrodes 12 to be driven. In other words, the electrode on one side of the group is added, while the electrode on the opposite side of the group is no longer driven. The new group is then driven by the P, N generator 22 and a second measurement of the sense line 16 is taken.

From these two measurements, it is possible to determine on which side of the row electrode 12 the pointing object is located, and how far away. Using an equation that compares the magnitude of the two signals measured then performs pointing object position determination.

The sensitivity or resolution of the CIRQUE® Corporation touchpad is much higher than the 16-by-12 grid of row 12 and column 14 electrodes implies. The resolution is typically on the order of 960 counts per inch, or greater. The exact resolution is determined by the sensitivity of the components, the spacing between the electrodes 12, 14 on the same rows and columns, and other factors that are not material to the present disclosure. The process above is repeated for the Y or column electrodes 14 using a P, N generator 24.

Although the CIRQUE® touchpad described above uses a grid of X and Y electrodes 12, 14 and a separate and single sense electrode 16, the sense electrode can actually be the X or Y electrodes 12, 14 by using multiplexing.

### SUMMARY

In a first embodiment, the present invention is a system and method for enabling noise avoidance between multiple capacitive touch sensing circuits operating in a same device or an adjacent environment and which may interfere with each other, wherein a master controller is coupled to all of the capacitive touch sensing circuits to prevent them from using measurement frequencies and from jumping to new measurement frequencies that may interfere with each other, thereby allowing the capacitive touch sensing circuits to function properly.

Another disclosed embodiment includes a first touch sensor in communication with a first touch controller, the first touch controller configured with a known maximum noise level threshold and optimal scan rate, and a plurality of first potential operating frequencies, a second touch sensor in communication with a second touch controller, the second touch controller configured with a known maximum noise level threshold and optimal scan rate, and a plurality of second potential operating frequencies. The first touch sensor and second touch sensor are located in an adjacent environment where noise interference can occur. The embodiments include a master controller in communication with the first touch controller and the second touch controller and wherein the master controller is configured to communicate particular ones of the first plurality of potential operating frequencies and the second plurality of potential operating frequencies. Further, the first touch controller scans the plurality of first potential operating frequencies against the particular ones communicated by the master controller and decides whether to select another of the first plurality of potential operating frequencies to reduce noise interference, and the second touch controller scans the plurality of second potential operating frequencies against the particular ones communicated by the master controller and decides whether to select another of the second plurality of potential operating frequencies to reduce noise.

Further disclosed embodiments include a third touch sensor in communication with a third touch controller, the third touch controller configured with a known maximum noise level threshold and optimal scan rate, and a plurality of third potential operating frequencies. The first touch sensor, second touch sensor, and third touch sensor are located in an adjacent environment where noise interference can occur. The master controller is in communication with the third touch controller wherein the master controller is configured to communicate particular ones of the third plurality of potential operating frequencies. The third touch controller scans the plurality of third potential operating frequencies against the particular ones communicated by the master controller and decides whether to select another of the third plurality of potential operating frequencies to reduce noise interference.

In further disclosed embodiments, the first touch controller, the second touch controller, and the third touch controller are configured to communicate a particular operating frequency in use to the master controller.

In further disclosed embodiments, the touch controllers are configured to decide whether to select another of the plurality of potential operating frequencies to reduce noise interference base at least in part upon at least one of their known maximum noise level threshold and optimal scan rate.

In further disclosed embodiments, the plurality of first potential operating frequencies and the plurality of second potential operating frequencies are different frequencies. In still further embodiments, the plurality of first potential operating frequencies and the plurality of second potential operating frequencies are overlapping frequencies.

In still further embodiments, the particular ones of the first plurality of potential operating frequencies and second plurality of potential operating frequencies comprise frequencies currently in use. In still further embodiments, the particular ones of the first plurality of potential operating frequencies and second plurality of potential operating frequencies comprise frequencies currently unavailable for use.

These and other objects, features, advantages and alternative aspects of the present invention will become apparent to those skilled in the art from a consideration of the following detailed description taken in combination with the accompanying drawings.

### BRIEF DESCRIPTION OF THE DRAWINGS

FIG. 1 is a block diagram of a touchpad system that is found in the prior art, and which is adaptable for use with presently disclosed embodiments.

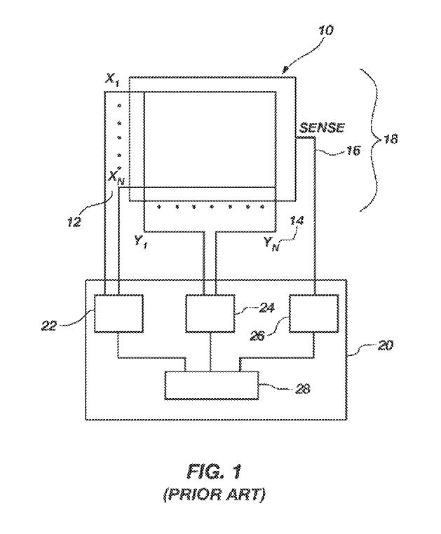

FIG. 2 is a flowchart of a method of interference avoidance using disclosed embodiments.

FIG. 3 is a flowchart of another method of interference avoidance using the disclosed embodiments.

FIG. 4 is a block diagram illustrating another embodiment showing a first touch sensing circuit, and second touch sensing circuit and a master controller circuit coupled to the first and second touch sensing circuits.

FIG. 5 is a schematic block diagram illustrating another embodiment of a touch sensor and touch controller in accordance with disclosed embodiments.

FIG. 6 is a schematic block diagram illustrating communications between sensors, touch controllers, and master controller in accordance with disclosed embodiments.

FIG. 7 is a schematic flow diagram illustrating methods of operation in accordance with disclosed embodiments.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION

It should be understood that use of the term “touch sensor” throughout this document may be used interchangeably with “forcepad,” “touchpad,” “proximity sensor,” “touch and proximity sensor,” “touch panel,” “touchpad,” and “touch screen.”

It should also be understood that, as used herein, the terms “vertical,” “horizontal,” “lateral,” “upper,” “lower,” “left,” “right,” “inner,” “outer,” etc., can refer to relative directions or positions of features in the disclosed devices and/or assemblies shown in the Figures. For example, “upper” or “uppermost” can refer to a feature positioned closer to the top of a page than another feature. These terms, however, should be construed broadly to include devices and/or assemblies having other orientations, such as inverted or inclined orientations where top/bottom, over/under, above/below, up/down, and left/right can be interchanged depending on the orientation.

In a first embodiment of the invention, there may be devices that require the use of more than one capacitive touch sensing circuit. For example, in a virtual reality (VR) controller, there may be a plurality of capacitive touch sensing circuits that are in operation at the same time. This is because there may be a need to be able to track the position of multiple fingers, the palm of a hand, or even fingers from two hands on a VR controller that a user may be touching.

For example, the user may be gripping the VR controller and using a trigger, while at the same time providing other buttons for other fingers. Alternatively, the user may be gripping the VR controller with one hand while also providing a touchpad on the top of the controller that may be manipulated by the other hand. The example of a VR controller should not be considered as limiting but only one example of a device that may incorporate at least two capacitive touch sensing circuits in the same device.

Most devices that incorporate a single capacitive touch sensing circuit have had to deal with noise and methods to either reduce noise or avoid noise in order to operate using a touch sensor. For example, the prior art has used frequency hopping to avoid noisy frequencies of operation. However, when using a device that incorporates more than one capacitive touch sensing circuit, the problem of noise becomes more complicated. Two independently operating capacitive touch sensing circuits may inadvertently end up selecting the same frequencies when trying to avoid noise if they are programmed to use the same measurement frequencies when avoiding noise. Thus, the problem that is addressed by the present disclosure is how to avoid interference between two or more capacitive touch sensing circuits that are operating in a same device such as a VR controller.

When using more than one capacitive touch sensing circuit that is capable of making capacitive measurements from electrodes, the measurement circuits may potentially interfere with each other if they use a prior art method of noise avoidance by frequency hopping. A first embodiment is to use capacitive touch sensing circuits that are preprogrammed to select measurement frequencies that are different from each other.

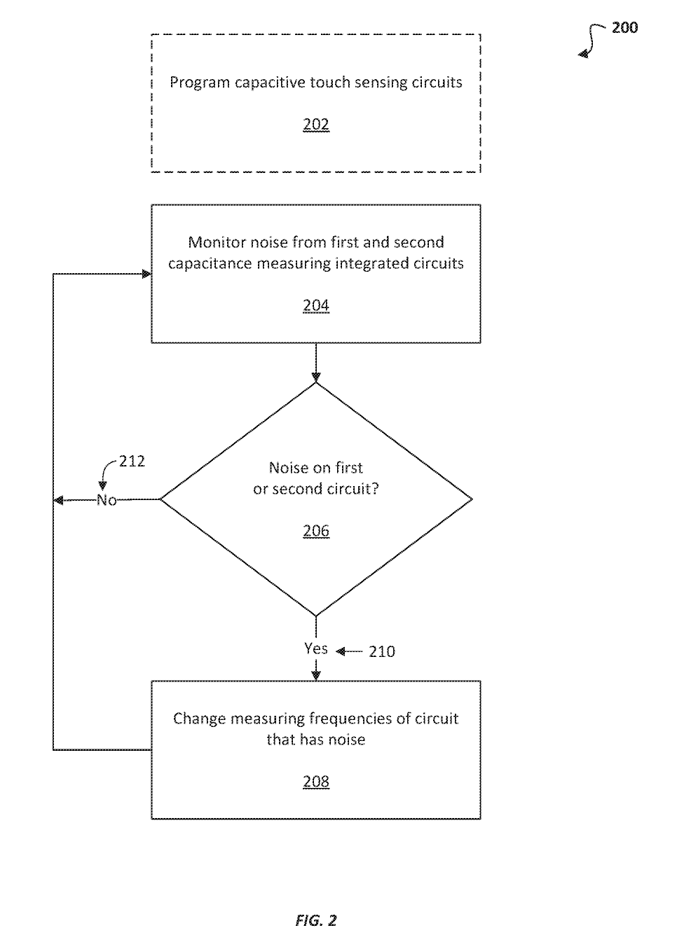

FIG. 2 illustrates a first embodiment of a method 200 of interference avoidance. The first step 202, which may occur at any time prior as indicated schematically by the dashed box, is to preprogram all of the capacitive touch sensing circuits to have different measurement frequencies. The next step 204 is to monitor noise being detected on the measuring frequency being used by each of the different capacitive touch sensing circuits. The next step 206 is to determine if noise is interfering with a measurement. If, as indicated at 210, noise is causing sufficient interference to be a problem, then at 208 the first embodiment changes the measuring frequency of any of the capacitive touch sensing circuits that are having difficulty making a measurement. If no noise was detected that required the measurement frequency of any of the capacitive touch sensing circuits to be changed, then at 212 the first embodiment continuously monitors for noise by return to step 204 until noise is detected that does require a change in measurement frequency (e.g., at 210).

Method 200 uses a kind of frequency hopping to avoid noise but should ensure all the measuring frequencies being used are different in each of the capacitive touch sensing circuits. One problem with using method 200 kind of frequency hopping is that any capacitive touch sensing circuits that fail should be replaced with a capacitive touch sensing circuits having the same measurement frequencies. This may be difficult to do if the preprogrammed measurement frequencies on each capacitive touch sensing circuits are not known or are difficult to determine.

Another problem that may occur is that because the capacitive touch sensing circuits are operating independently of each other, they may actually cause the very interference they are trying to avoid. For example, the capacitive touch sensing circuits typically include a set of four possible measurement frequencies. Noise from other sources may prohibit the use of some frequencies. However, a capacitive touch sensing circuit may be causing interference on a remaining measurement frequency. There is no method for coordinating with the capacitive touch sensing circuit that is causing interference.

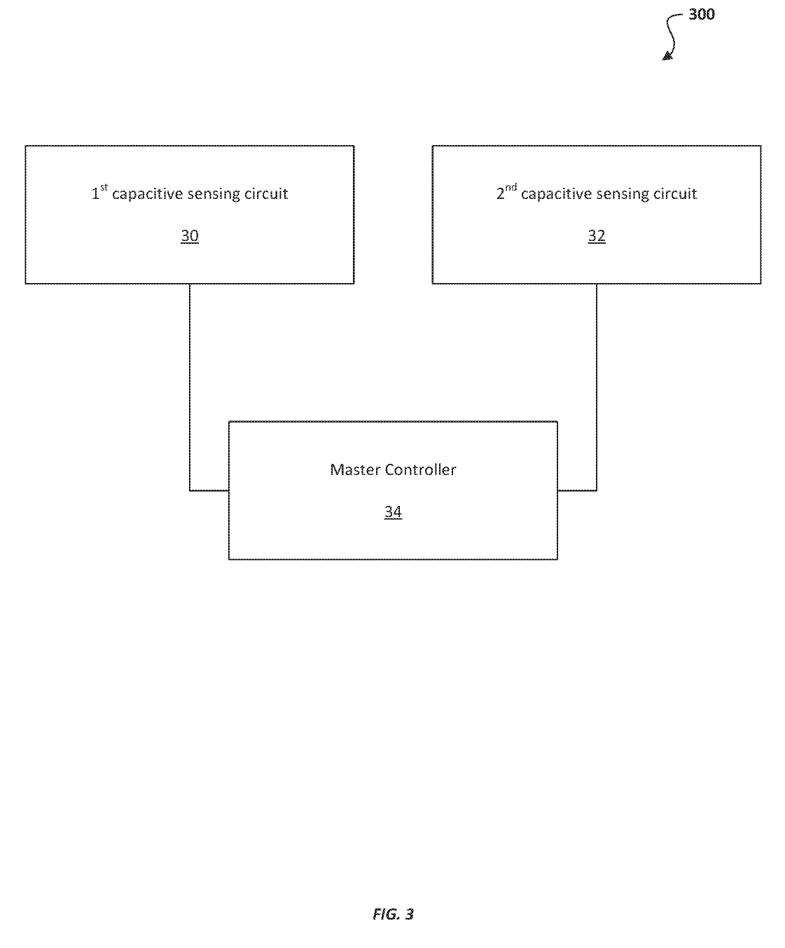

Accordingly, a second embodiment 300 may avoid the problem presented by the method 200 of uncoordinated frequency hopping in the first embodiment. In the second embodiment 300, shown in FIG. 3, schematically shows a master controller 34 is provided which is coupled to all of the capacitive touch sensing circuits. In FIG. 3 there is shown a first capacitive touch sensing circuit 30 and a second capacitive touch sensing circuit 32. The capacitive touch sensing circuits 30, 32 are no longer operating independently of each other but are instead being controlled by the master controller 34.

The master controller 34 may be connected to all of the capacitive touch sensing circuits 30, 32 that are provided in a single device. The purpose of the master controller 34 is to coordinate operation of all the separate capacitive touch sensing circuits 30, 32. By providing for coordinated operation of all the separate capacitive touch sensing circuits, it is possible to efficiently enable the capacitive touch sensing circuits 30, 32 to avoid noise while at the same time avoid interfering with each other.

For example, consider the problem presented by the first embodiment of the invention. A first capacitive touch sensing circuit may have a single measurement frequency available to it because of noise interference on its other possible frequencies. But that single measurement frequency might be in use by a second capacitive touch sensing circuit. However, the second capacitive touch sensing circuit may have another measurement frequency that it can also use. With the master controller, the second capacitive touch sensing circuit may be instructed to switch to one of the other measurement frequencies that are available. The first capacitive touch sensing circuit may then use its only available measurement frequency that has been made available.

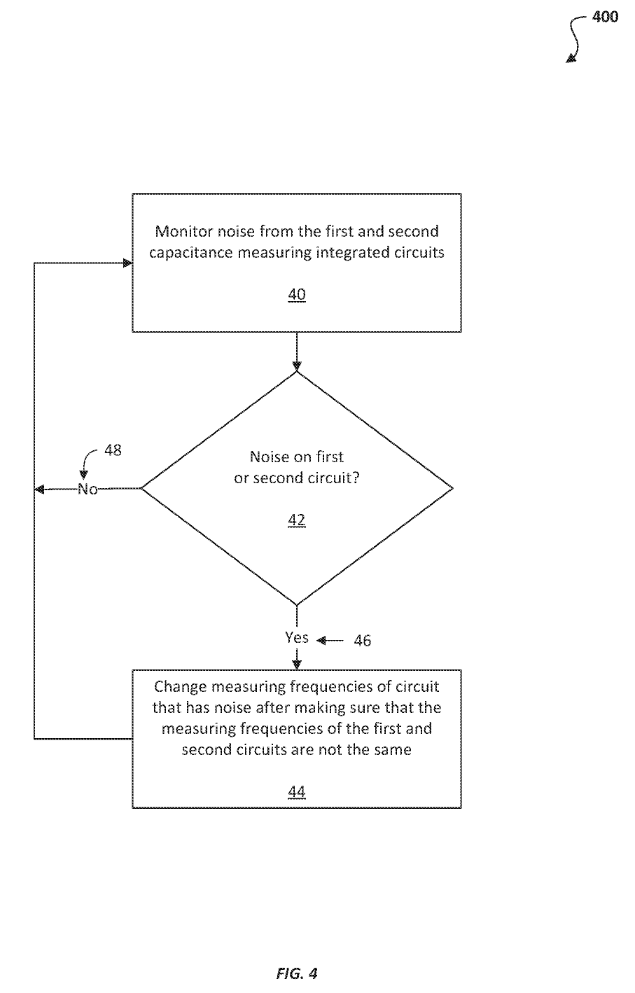

Accordingly, the steps of another embodiment of a method 400 for interference avoidance is shown in FIG. 4. A first difference of this embodiment is that preprogramming of measurement frequencies (e.g., step 202) is no longer required because the master controller (e.g., 34) will know which measurement frequencies are being used by all of the capacitive touch sensing circuits (e.g., 30, 32) in the device. Thus, all of the capacitive touch sensing circuits (e.g., 30, 32) may now be identical and not require preprogramming.

The first step 40 of the method 400 is to monitor noise on the measuring frequencies of all the capacitive touch sensing circuits.

The next step 42 is to determine if there is noise on any of the measurement frequencies that will prevent the accurate collection of data from a measurement frequency.

If there is noise detected as indicated at 46, then the next step 44 is to change the measurement frequency on all of the capacitive touch sensing circuits using the master controller. The new measurement frequencies may be selected so as to not cause interference with capacitive touch sensing circuits that do not have noise interference. The selection of new measurement frequencies will be much more efficient because the selection is not being made blindly. The master controller already knows the measurement frequencies being used and may therefore avoid any potential interference that could be caused by a new measurement frequency. In addition, if noise is not detected as indicated at 48, the method returns to step 40 to continue monitoring noise.

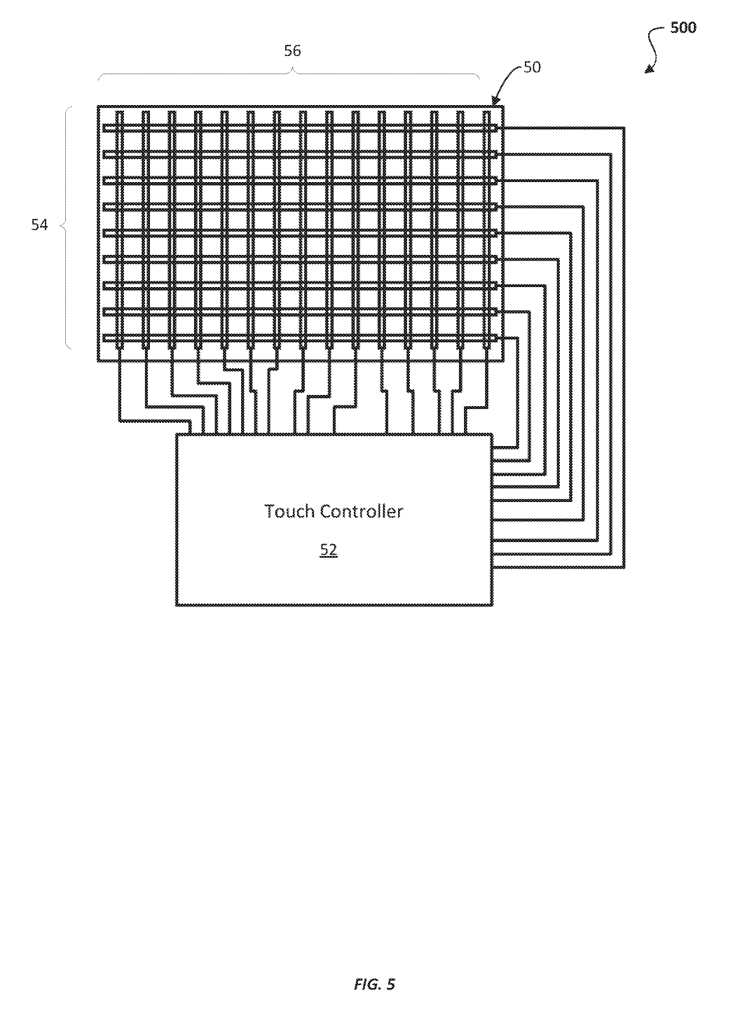

FIG. 5 is a schematic block diagram illustrating another embodiment 500 of a touch sensor 50 and touch controller 52 in accordance with disclosed embodiments. As shown, a number of X or row electrodes 54 and Y or column electrodes 56 are provided with touch sensor 50 and communicate with touch controller 52 to, among other things, sense capacitive coupling when an object approaches or touches a touch surface as would be understood by persons of ordinary skill in the art having the benefit of this disclosure. As would also be understood, the sense electrode can be one of the X (row 54) or Y (column 56) electrodes by using multiplexing controlled by the touch controller 52.

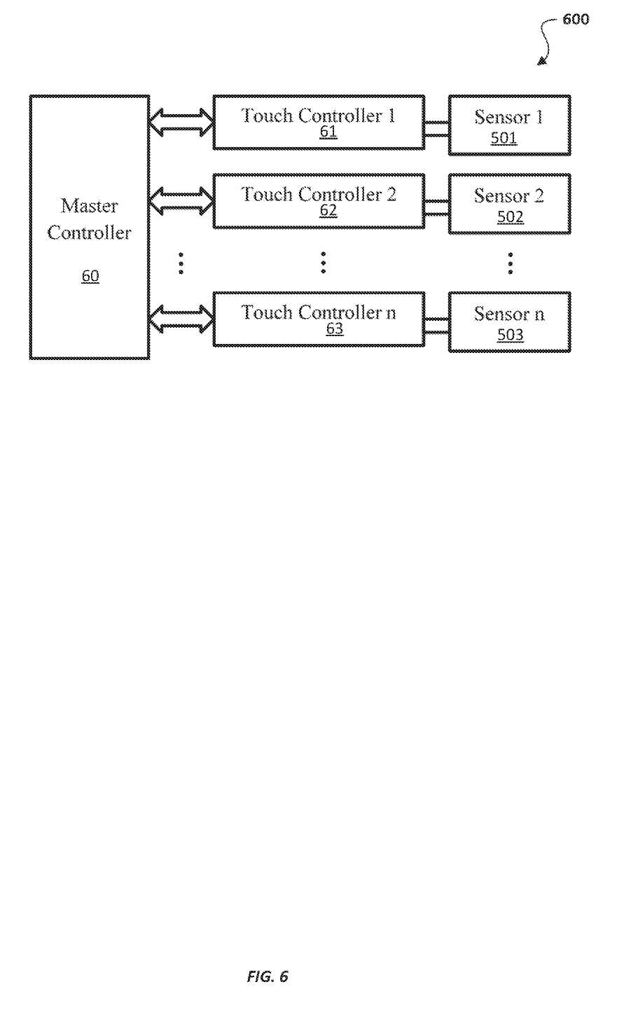

As disclosed herein, touch sensors (e.g., touch sensor 50) are subject to noise input from the user's fingers and from other nearby electrical noise sources. Further, when more than one touch sensor is used in one system and adjacent to each other, they can cause noise in each other. To mitigate, reduce, or eliminate these noise issues, touch controller 52 which may include a central processing unit (CPU), a digital signal processor (DSP), a peripheral interface controller (PIC), another type of microprocessor, and/or combinations thereof, and may be implemented as an integrated circuit, a field programmable gate array (FPGA), an application specific integrated circuit (ASIC), a combination of logic gate circuitry, other types of digital or analog electrical design components, or combinations thereof, with appropriate circuitry, hardware, firmware, and/or software to choose from available frequencies to operate. For example, in some embodiments each touch controller 52 is configured, programmed, or equipped to know what level of noise is too much (e.g., maximum level), and how fast the controller's scan rate needs to be for its optimal operation. By way of further example, and with reference to FIG. 6, one touch sensor 501 might need to track a fast thumb swipe on a game controller trackpad while another touch sensor 502 in the system 600 might need to just measure proximity of gripping fingers. These two examples have different scan rate requirements so each touch controller 61, 62, is best suited to pick its own toggling frequencies, rather than have master controller 60 dictating toggling frequencies.

FIG. 6 is a schematic block diagram illustrating communications between touch sensors 501, 502, 503, touch controllers 61, 62, 63, and master controller 60 in accordance with disclosed embodiments. As indicated by the schematic, the presently disclosed systems and methods may be extended to any number (“n”) of touch controllers 61, 62, 63 and touch sensors 501, 502, 503. Likewise, while one master controller 60 is indicated schematically, more than one master controller 60, a distributed master controller (i.e., located in more than one location with cooperative operation), or the like can be included in system 600. Further, master controller 60 may include may include a central processing unit (CPU), a digital signal processor (DSP), a peripheral interface controller (PIC), another type of microprocessor, and/or combinations thereof, and may be implemented as an integrated circuit, a field programmable gate array (FPGA), an application specific integrated circuit (ASIC), a combination of logic gate circuitry, other types of digital or analog electrical design components, or combinations thereof, with appropriate circuitry, hardware, firmware, and/or software.

As indicated by FIG. 6, and disclosed herein, master controller 60 is configured to communicate to each touch controller 61, 62, 63 all the available toggle frequencies each touch controller 61, 62, 63 may use to operate. In some embodiments, the available frequencies communicated by master controller 60 for any given touch controller 61, 62, 63 may, or may not, overlap with the set of available frequencies communicated to the other touch controllers 61, 62, 63.

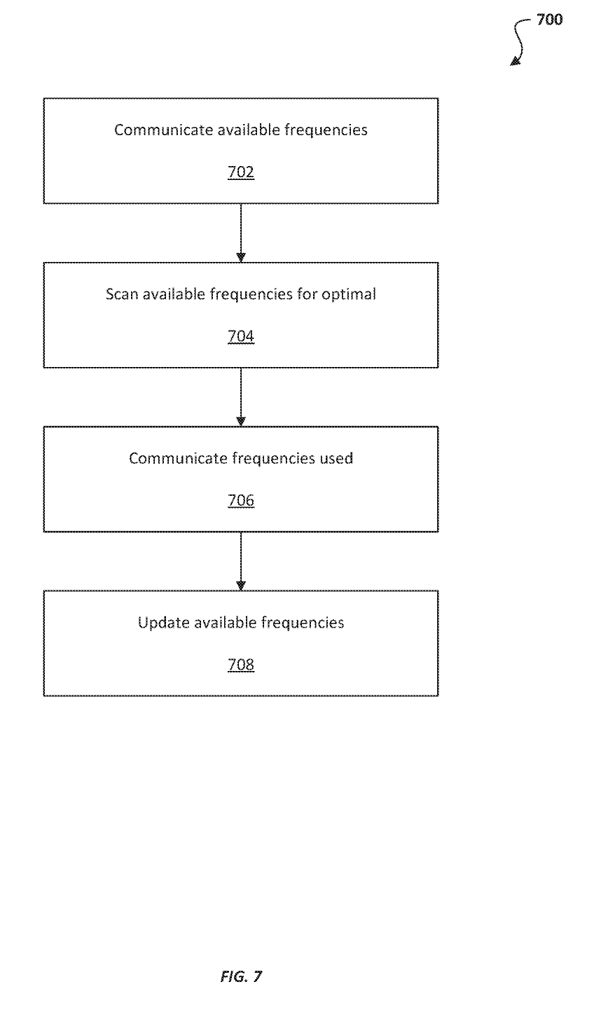

FIG. 7 is a schematic flow diagram illustrating a general method of operation 700 for system 600 in accordance with disclosed embodiments. As disclosed herein, upon occurrence of detected noise at one or more of the “n” touch sensors 501, 502, 503, master controller 60 communicates the available frequencies of operation to the “n” touch controllers 61, 62, 63. At 704 each touch controller 61, 62, 63 scans the communicated available frequencies for best, or acceptable, optimal frequency.

At 706 each touch controller 61, 62, 63 communicates to the master controller 60 the particular frequency it is using. The master controller 60 updates a table of used frequencies with the set (or sets) now in use.

As one of ordinary skill in the art would appreciate, master controller 60 may also communicate a list of unavailable frequencies to the “n” touch controllers 61, 62, 63 which may store a set of potentially useable frequencies. Upon detection of noise, each touch controller 61, 62, 63 scans the frequencies that are unavailable to switch to and switches to another frequency that is available in its set of potentially useable frequencies. The master controller 60 is again updated with the new set of frequencies in use.

Although various embodiments have been shown and described, the present disclosure is not so limited and will be understood to include all such modifications and variations are would be apparent to one skilled in the art.

What is claimed is:

1. A system comprising:
a first touch sensor in communication with a first touch controller, the first touch controller configured with a known maximum noise level threshold and optimal scan rate, and a plurality of first potential operating frequencies;
a second touch sensor in communication with a second touch controller, the second touch controller configured with a known maximum noise level threshold and optimal scan rate, and a plurality of second potential operating frequencies;
wherein the first touch sensor and second touch sensor are located in an adjacent environment where noise interference can occur; and
a master controller in communication with the first touch controller and the second touch controller and wherein the master controller is configured to communicate particular ones of the first plurality of potential operating frequencies and the second plurality of potential operating frequencies; and
wherein the first touch controller scans the plurality of first potential operating frequencies against the particular ones communicated by the master controller and decides whether to select another of the first plurality of potential operating frequencies to reduce noise interference; and
wherein the second touch controller scans the plurality of second potential operating frequencies against the particular ones communicated by the master controller and decides whether to select another of the second plurality of potential operating frequencies to reduce noise.

2. The system of claim 1 further comprising:
a third touch sensor in communication with a third touch controller, the third touch controller configured with a known maximum noise level threshold and optimal scan rate, and a plurality of third potential operating frequencies;
wherein the first touch sensor, second touch sensor, and third touch sensor are located in an adjacent environment where noise interference can occur; and
the master controller is in communication with the third touch controller wherein the master controller is configured to communicate particular ones of the third plurality of potential operating frequencies; and
wherein the third touch controller scans the plurality of third potential operating frequencies against the particular ones communicated by the master controller and decides whether to select another of the third plurality of potential operating frequencies to reduce noise interference.

3. The system of claim 1 wherein the first touch controller and the second touch controller are configured to communicate a particular operating frequency in use to the master controller.

4. The system of claim 2 wherein the third touch controller is configured to communicate a particular operating frequency in use to the master controller.

5. The system of claim 1 wherein first touch controller is configured to decide whether to select another of the first plurality of potential operating frequencies to reduce noise interference base at least in part upon at least one of its known maximum noise level threshold and optimal scan rate.

6. The system of claim 1 wherein the plurality of first potential operating frequencies and the plurality of second potential operating frequencies are different frequencies.

7. The system of claim 1 wherein the plurality of first potential operating frequencies and the plurality of second potential operating frequencies are overlapping frequencies.

8. The system of claim 1 wherein the particular ones of the first plurality of potential operating frequencies and second plurality of potential operating frequencies comprise frequencies currently in use.

9. The system of claim 1 wherein the particular ones of the first plurality of potential operating frequencies and second plurality of potential operating frequencies comprise frequencies currently unavailable for use.

10. A method for decreasing interference between at least two capacitive touch sensing circuits, said method comprising:
providing a first capacitive touch sensing circuits that includes both driven electrodes and at least one sense electrode;
providing a second capacitive touch sensing circuit that includes both driven electrodes and at least one sense electrode, wherein the first capacitive touch sensing circuit and the second capacitive touch sensing circuit are operating in an adjacent environment wherein there is interference;
providing a master controller that is coupled to the first and second capacitive touch sensing circuits and which monitors the measurement frequencies selected by the first and second capacitive touch sensing circuits;
measuring a signal using the first or the second touch sensing circuits;
detecting noise when measuring the signal;
using the master controller to supply a new measurement frequency for the first or second capacitive touch sensing circuits when noise is detected that interferes with operation of the first or second capacitive touch sensing circuits;
enabling at least one of the first or second capacitive touch sensing circuits to change measuring frequencies to the new measurement frequency when noise is detected, wherein the new measurement frequency is selected so that it does not interfere with operation of the other capacitive touch sensing circuit.

11. The method as defined in claim 10 wherein the method further comprises:
providing a third capacitive touch sensing circuit that includes both driven electrodes and at least one sense electrode; and
coupling the master controller to the third capacitive touch circuit, wherein the first, second and third capacitive touch sensing circuits are operating in an adjacent environment wherein when there is interference, the master controller coordinates operation of the first, second, and third capacitive touch circuits.

12. The method as defined in claim 10 wherein the method further comprises:
providing a plurality of additional capacitive touch sensing circuits that include both driven electrodes and at least one sense electrode; and
coupling the master controller to the plurality of capacitive touch circuits, wherein the first, second and plurality of capacitive touch sensing circuits are operating in an adjacent environment wherein there is interference, the master controller coordinates operation of the first, second and plurality of capacitive touch circuits.

13. A system for decreasing interference between at least two capacitive touch sensing circuits, said system comprised of:
a first capacitive touch sensing circuit that includes both driven electrodes and at least one sense electrode;
a second capacitive touch sensing circuit that includes both driven electrodes and at least one sense electrode, wherein the first capacitive touch sensing circuit and the second capacitive touch sensing circuit are operating in an adjacent environment wherein there is interference between them;
a master controller circuit that is coupled to the first and second capacitive touch sensing circuits and which controls the measurement frequencies selected by the first and second capacitive touch sensing circuits, wherein the first and second capacitive touch sensing circuits monitor noise when detecting a signal, and the master controller circuit supplies a new measurement frequency for the first or second capacitive touch sensing circuits when noise is detected that interferes with operation of the first or second capacitive touch sensing circuits, wherein the new measurement frequency is selected so that it does not interfere with operation of the other capacitive touch sensing circuit.

14. The system of claim 13 wherein the system further comprises:
a third capacitive touch sensing circuit that includes both driven electrodes and at least one sense electrode, wherein the third capacitive touch sensing circuit is coupled to the master controller, wherein the first, second and third capacitive touch sensing circuits are operating in an adjacent environment wherein there is interference between them, such that the master controller coordinates operation of the first, second and third capacitive touch circuits.

15. The system as defined in claim 13 wherein the system is further comprised of a plurality of capacitive touch sensing circuits that include both driven electrodes and at least one sense electrode, wherein the plurality of capacitive touch sensing circuits are coupled to the master controller, wherein the first, second and plurality of capacitive touch sensing circuits are operating in an adjacent environment wherein there is interference between them, such that the master controller coordinates operation of the first, second and plurality of capacitive touch circuits.
